(19) United States
(12) Patent Application Publication
(10) Pub. No.: US 2007/0272922 A1
(43) Pub. Date: Nov. 29, 2007

(54) ZnO thin film transistor and method of forming the same

(75) Inventors: Chang-jung Kim, Yongin-si (KR); I-hun Song, Seongnam-si (KR); Dong-hun Kang, Yongin-si (KR); Young-soo Park, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/702,222

(22) Filed: Feb. 5, 2007

(30) Foreign Application Priority Data
Apr. 11, 2006 (KR) 10-2006-0032787

(51) Int. Cl. H01L 29/12; H01L 21/00

(52) U.S. Cl. 257/43; 438/104; 257/E21.001; 257/E29.068

(57) ABSTRACT

A zinc oxide (ZnO) thin film transistor (TFT) and method of forming the same are provided. The ZnO may include a ZnO semiconductor channel, a conductive ZnO gate forming an electric field around the ZnO semiconductor channel, an ZnO gate insulator interposed between the conductive ZnO gate and the ZnO semiconductor channel and an insulating ZnO passivation layer on the ZnO semiconductor channel, the conductive ZnO gate and the ZnO gate insulator to protect the ZnO semiconductor channel, the conductive ZnO gate, and the ZnO gate insulator. A thin film transistor (TFT) may be formed by forming a semiconductor channel, forming a conductive gate having an electric field around the semiconductor channel, forming a gate insulator between the conductive gate and the semiconductor channel, and forming an insulating passivation layer on the semiconductor channel, the conductive gate and the gate insulator.

### PRIORITY STATEMENT

This application claims the benefit of Korean Patent Application No. 10-2006-0032787, filed on Apr. 11, 2006 in the Korean Intellectual Property Office, the disclosure of which is incorporated herein in its entirety by reference.

### BACKGROUND

1. Field

Example embodiments relate to a zinc oxide (ZnO) thin film transistor (TFT) and method of forming the same. Example embodiments relate to a ZnO TFT that may be manufactured at lower temperature and method of forming the same.

2. Description of the Related Art

Silicon thin film transistor-liquid crystal displays (TFT-LCDs) may include glass substrates, making the TFT-LCDs heavy and inflexible. As such, it is not desirable to fabricate TFT-LCDs including glass substrates as flexible displays. Recently research has been performed on organic semiconductor materials and metal oxide semiconductor materials to address problems with conventional TFT-LCDs.

A metal oxide semiconductor (e.g., a ZnO semiconductor) may be applied to TFTs, sensors, optical wave guides, piezoelectric elements or the like. A ZnO film having a higher quality may be produced by growing the ZnO film at a higher temperature of 400° C. or higher. However, growth at such high temperature limits the materials that may be used to form a substrate. For example, a plastic, which is susceptible to heat damage, may not be used to form a substrate.

According to the conventional art, a substrate may be heated at a temperature between 350° C. and 450° C. during the growth of ZnO crystals. In other example embodiments, the ZnO crystals may be grown at a temperature between 600° C. and 900° C.

Materials used for a conventional ZnO TFT will now be described.

A channel of a conventional ZnO TFT may be formed of zinc oxide (ZnO). A source and a drain contacting ends of the channel and a gate forming an electric field around the channel may be formed of a metal (e.g., molybdenum (Mo) or the like). A gate insulating layer between the gate and the channel may be formed of a silicon nitride (SiNₓ) or silicon dioxide (SiO₂). A protective (or passivation) layer formed of silicon dioxide (SiO₂) or a silicon nitride (SiNₓ) is formed on a transistor having the structure described above in order to insulate and/or protect elements formed on the transistor.

The conventional ZnO TFT may include elements formed of various materials. The type of material used may be selected based on the process to be performed. For example, silicon dioxide (SiO₂), a silicon nitride (SiNₓ) or the like may be used in a higher temperature process. In the conventional art, it is undesirable to form a substrate from plastic because plastic is susceptible to heat damage.

### SUMMARY

Example embodiments relate to a zinc oxide (ZnO) thin film transistor (TFT) and method of forming the same. Example embodiments relate to a ZnO TFT that may be manufactured at lower temperature and method of forming the same.

Example embodiments provide a ZnO TFT that fabricated at a lower temperature by adopting a lower temperature fabrication process. As such, the ZnO TFT may use a material susceptible to heat damage (e.g., plastic) as a substrate.

According to example embodiments, there is provided a ZnO (thin film transistor (TFT) including a ZnO semiconductor channel, a conductive ZnO gate forming an electric field around the ZnO semiconductor channel, an ZnO gate insulator interposed between the conductive ZnO gate and the ZnO semiconductor channel and an insulating ZnO passivation layer formed on the ZnO semiconductor channel, the conductive ZnO gate and the ZnO gate insulator to protect the ZnO semiconductor channel, the conductive ZnO gate, and the ZnO gate insulator.

The conductive ZnO gate may be formed between the semiconductor channel and the passivation layer. In other example embodiments, the conductive ZnO gate may be formed between the semiconductor channel and a substrate. The conductive ZnO gate may be formed of ZnO doped with a conductive material. The conductive ZnO gate, a source and a drain may be formed of amorphous ZnO.

The ZnO semiconductor channel may be formed of ZnO doped with a conductive material. The ZnO semiconductor channel may be formed of polycrystalline ZnO.

According to other example embodiments, a thin film transistor (TFT) may be formed by forming a semiconductor channel, forming a conductive gate having an electric field around the semiconductor channel, forming an gate insulator between the conductive gate and the semiconductor channel, and forming an insulating passivation layer on the semiconductor channel, the conductive gate and the gate insulator.

### BRIEF DESCRIPTION OF THE DRAWINGS

Example embodiments will be more clearly understood from the following detailed description taken in conjunction with the accompanying drawings. FIGS. 1-8 represent non-limiting, example embodiments as described herein.

FIG. 1 is a diagram illustrating a schematic cross-sectional view of a top gate type ZnO TFT according to example embodiments;

FIG. 2 is a diagram illustrating a schematic cross-sectional view of a bottom gate type ZnO TFT according to example embodiments;

FIG. 3 is a spectrum showing crystal orientations of ZnO thin films formed using radio frequency (RF) magnetron sputtering according to example embodiments;

FIG. 4 is a spectrum showing crystal orientations of an X-ray diffraction (XRD) analysis of a ZnO insulating material formed using RF magnetron sputtering according to example embodiments;

FIG. 5 is a spectrum showing crystal orientations of an XRD analysis of a crystallization degree of a ZnO semiconductor material according to example embodiments;

FIG. 6 is a graph of a gate voltage V_{G} and a drain current I_{D} of a ZnO gate oxide according to example embodiments;

FIG. 7 is a graph of a gate voltage V_{G} and a drain current I_{D} of a ZnO semiconductor channel according to example embodiments; and

FIG. 8 is a graph of a drain voltage V_{D} and a drain current I_{D} of a ZnO semiconductor channel according to example embodiments.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to a zinc oxide (ZnO) thin film transistor (TFT) and method of forming the same. Example embodiments relate to a ZnO TFT that may be manufactured at lower temperature and method of forming the same.

Example embodiments use a RF magnetron sputtering method by which a ZnO TFT is fabricated through a process temperature of 300° C. or less enabling a lower temperature process to be performed.

A ZnO TFT according to example embodiments will now be described.

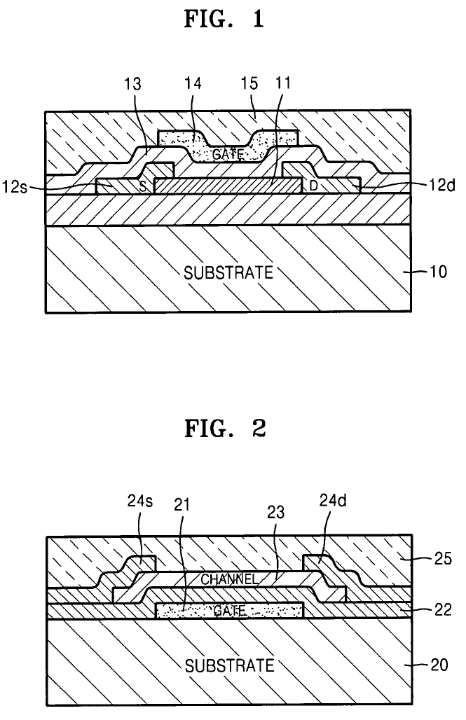

FIG. 1 is a diagram illustrating a schematic cross-sectional view of a top gate type ZnO TFT according to example embodiments.

Referring to FIG. 1, a ZnO semiconductor channel 11 is formed on a substrate 10. The ZnO semiconductor channel 11 may be formed of an opaque or transparent material. A source 12s and a drain 12d are formed on different sides of the ZnO semiconductor channel 11. The source 12s and the drain 12d may overlap with the sides of the ZnO semiconductor channel 11 by a desired distance. A gate insulator 13, which may be formed of insulating ZnO, is formed on the ZnO semiconductor channel 11, the source 12s and the drain 12d. A ZnO gate 14 is formed on the gate insulator 13 facing (or having a portion indented toward) a central portion of the ZnO semiconductor channel 11. A passivation layer 15 for insulating (or protecting) ZnO is formed on the ZnO gate 14 to cover (or passivate) the ZnO gate 14 and the gate insulator 13.

FIG. 2 is a diagram illustrating a schematic cross-sectional view of a bottom gate type ZnO TFT according to example embodiments.

Referring to FIG. 2, a ZnO gate 21 is formed on a substrate 20. A ZnO gate insulator 22 is formed on the ZnO gate 21. A ZnO semiconductor channel 23 is formed on the gate insulator 22 facing (or having end portions indented toward) the gate 21. The end portions of the ZnO semiconductor channel 23 may extend beyond the sides of the gate 21. A source 24s and a drain 24d are formed on a portion of the gate insulator 22 and on sides of the ZnO semiconductor channel 23. The source 24s and the drain 24d may be formed over portions of the gate insulator 22 not overlapping with the ZnO gate 21. The source 24s and the drain 24d overlap with the ends of the ZnO semiconductor channel 23 by a desired distance. A passivation layer 25, which may be formed of insulating ZnO, is formed on the ZnO semiconductor channel 23, the source 24s and the drain 24d.

The substrates 10 and 20 may be formed of opaque or transparent materials depending on the application of the ZnO TFTs. For example, if a ZnO TFT according to example embodiments will be applied to an organic light emitting display using a bottom emitting method, a substrate thereof may be formed of a transparent material.

The ZnO TFTs according to example embodiments are characterized in that conductive materials, semiconductor materials and insulating materials of the ZnO TFTs may be formed of zinc oxide (ZnO). Electrical characteristics of ZnO may be adjusted by changing an oxygen partial pressure during formation of a ZnO layer thereof. Methods for adjusting the electrical characteristics of ZnO are well-known and therefore a description thereof will be omitted.

In the ZnO TFTs according to example embodiments, the ZnO gates may have a thickness of about 200 nm. The sources and the drains each may have a thickness of about 100 nm. The gate insulators may have a thickness of about 200 nm. The channels may have a thickness of about 70 nm.

The ZnO gate, the source and the drain are good conductors, requiring a lower specific resistance. If ZnO crystals of crystal orientations (100), (002) and (101) are mixed, then a lower specific resistance may be obtained.

In example embodiments, at least one of a ZnO source, a ZnO drain, a ZnO gate and a ZnO channel may include a conductive material (e.g., indium (In), gallium (Ga) or the like) as a dopant. At least one of the ZnO source, the ZnO drain, the ZnO gate and the ZnO channel may be formed of amorphous ZnO.

According to example embodiments, the ZnO channel may be formed of polycrystalline ZnO.

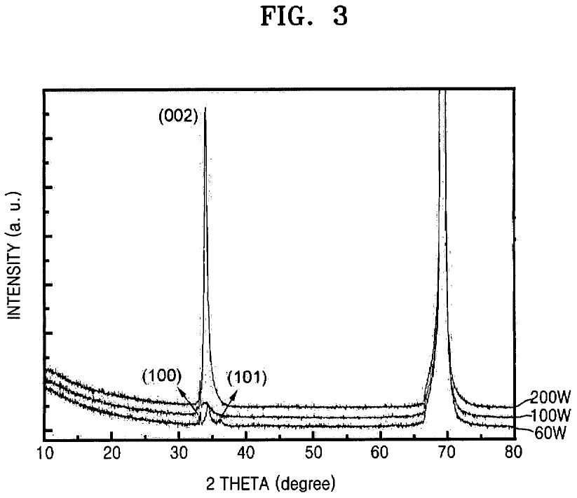

FIG. 3 is a spectrum showing crystal orientations of ZnO thin films formed on a silicon (Si) substrate by radio frequency (RF) magnetron sputtering at 60 W, 100 W and 200 W according to example embodiments. The ZnO thin films were formed in an atmosphere of pure argon (Ar) having no oxygen in order to be suitable for forming a gate, a source and a drain.

Referring to FIG. 3, ZnO having crystal orientations (100), (002) and (101) is observed at an output of 60 W. A mixture of ZnO having a crystal orientation (100) and amorphous ZnO is observed when the corresponding thin film is formed by RF magnetron sputtering at 100 W. A ZnO having a crystal orientation (002) is observed when RF magnetron sputtering at 200 W.

Crystal orientations and specific resistances of ZnO thin films for each respective RF power used to grow the corresponding ZnO TFT are shown in Table 1. The ZnO TFTs are grown in an atmosphere of pure argon (Ar).

TABLE 1

| | RF Power | | |
|---|---|---|---|
| | 60 W | 100 W | 200 W |
| Orientation | Mixture of (100), | (100) and | (002) |
| | (002) and (101) | Amorphous | |
| Specific Resistance | 8.7 * 10E−3 | 2.7 * 10E−2 | 2.7 * 10E−1 |
| (Ω · cm) | | | |

As shown in Table 1, the ZnO thin film formed by RF magnetron sputtering at 60 W has the lowest specific resistance of the films. The ZnO thin film formed by RF magnetron sputtering at 60 W includes a mixture of ZnO crystals having orientations (100), (002), and (101).

The ZnO thin film formed by RF magnetron sputtering at 100 W includes a mixture of crystal ZnO having the orientation (100) and amorphous ZnO. A ZnO thin film formed by RF magnetron sputtering at 200 W includes a crystal having a desired orientation (002).

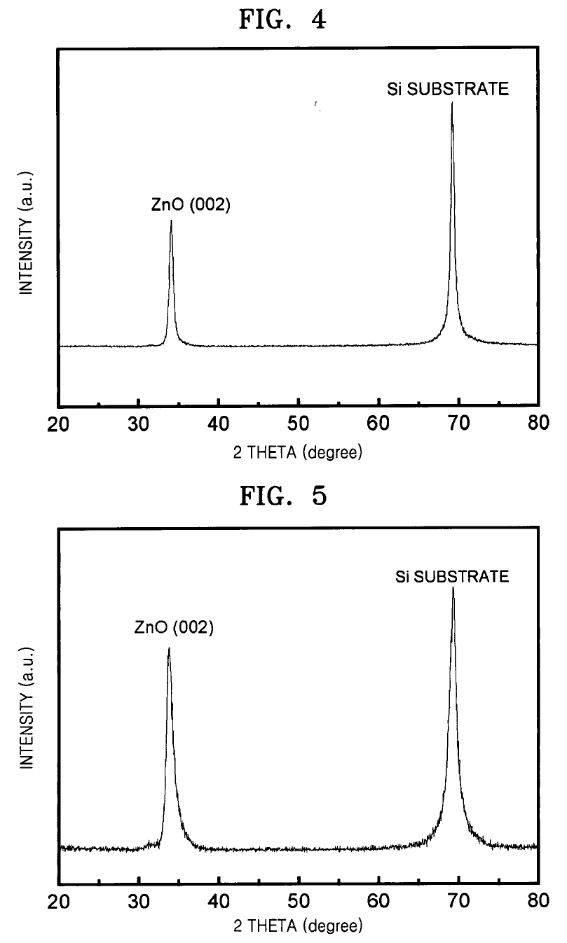

FIG. 4 is a spectrum showing crystal orientations of an XRD analysis of ZnO insulating materials formed by RF magnetron sputtering according to example embodiments. The RF magnetron sputtering is performed at 200 W in an argon (Ar) atmosphere including oxygen adjusted to 40% with respect to argon (Ar).

Referring to FIG. 4, ZnO having a crystal orientation (002) is the only orientation observed. As such, a ZnO insulating material may be used to form the gate insulator and the passivation layer according to example embodiments. The argon (Ar) atmosphere may include 1% to 100% oxygen based on 100% atmospheric Ar. The RF magnetron sputtering may be performed in a range of 100 W to 300 W. The ZnO insulating material has a thickness in a range of 50 nm to 200 nm.

FIG. 5 is a spectrum showing crystal orientations of an XRD analysis of the crystallization degree of a ZnO semiconductor material formed by RF magnetron sputtering at 200 W according to example embodiments. The ZnO semiconductor was formed in an argon (Ar) atmosphere containing 0.1% oxygen.

Referring to FIG. 5, ZnO having crystal orientation (002) is the only orientation observed in the ZnO semiconductor material. As such, a ZnO semiconductor material may be used to form a channel of a ZnO TFT according to example embodiments. The Ar atmosphere included 0.001% to 1% oxygen with respect to Ar. The RF magnetron sputtering was performed in a range of 100 W to 300 W. The ZnO semiconductor material had a thickness in a range of 30 nm to 100 nm.

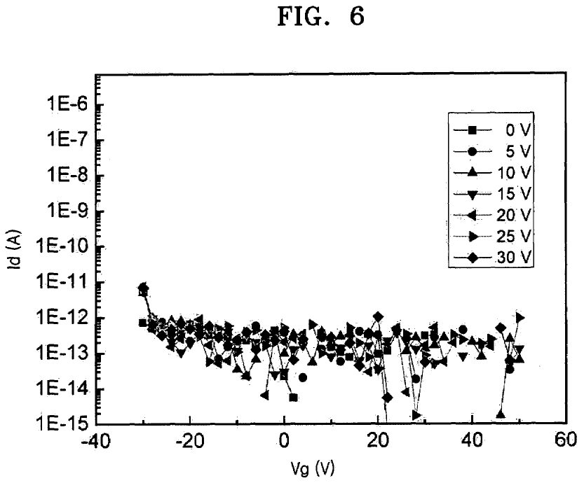

FIG. 6 is a graph of gate voltage V_{G} and drain current I_{D} of a ZnO gate oxide showing electrical insularity characteristics of ZnO gate oxide according to example embodiments. FIG. 6 shows variations in the gate voltage V_{G} and drain current I_{D} with respect to source-drain voltages 0V, 5V, 10V and 15V-30V.

Referring to FIG. 6, a current value of 1E-12A or less remains fairly constant when the gate voltage is increased to 50V. The ZnO gate oxide may be a good insulator. The ZnO gate oxide may be used as a gate insulator or a passivation layer.

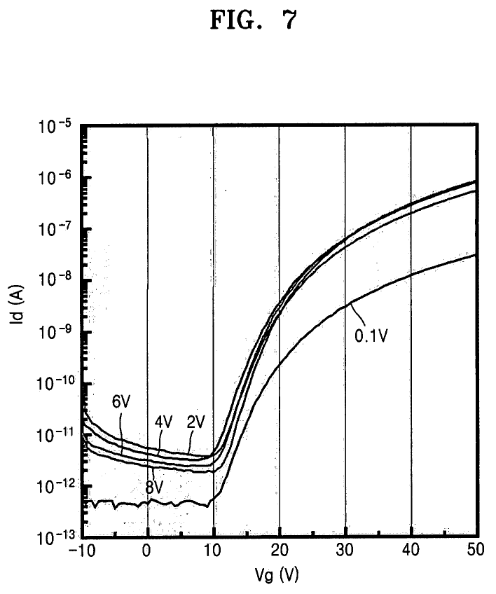

FIG. 7 is a graph of gate voltage V_{G} an drain current I_{D} of a ZnO semiconductor channel showing electric characteristics the ZnO semiconductor channel according to example embodiments. The graph shows variations in gate voltage V_{G} and drain current I_{D} with respect to source-drain voltages of 0.1, 2, 4, 6 and 8V.

If the gate voltage V_{G} is zero, then a drain current is 1E-11A or less. If the gate voltage is 50V, then a drain current is 10E-7A. As such, an on-off current ratio is 1E5 or more. A switching characteristic by which a current is turned off and turned on using a TFT is realized.

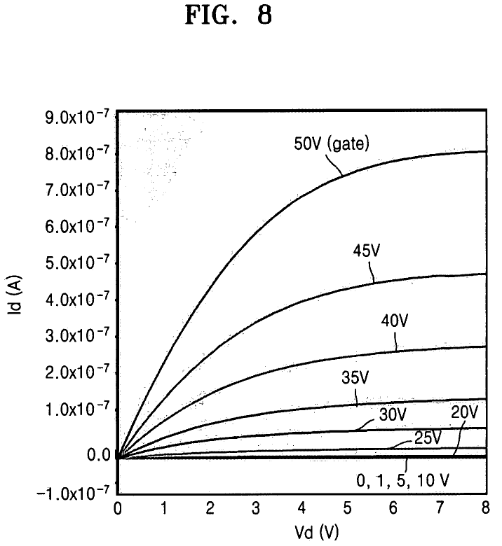

FIG. 8 is a graph of drain voltage V_{D} and drain current I_{D} of a ZnO semiconductor channel showing electric characteristics of the ZnO semiconductor channel according to example embodiments. The graph shows variations in a drain voltage V_{D} and a drain current I_{D} with respect to gate voltages of 0.1V to 50V.

Referring to FIG. 8, a voltage is applied to a gate in phase to increase a current flowing between a source and a drain while increasing amplification of a drain voltage. The electric characteristics of the ZnO semiconductor channel correlate with the electric characteristics of the ZnO semiconductor channel shown in FIG. 7. As such, the ZnO TFT may function as a switch because a current flows between a source and a drain with an increased gate voltage.

As described above, a ZnO TFT according to example embodiments may be fabricated at a room temperature or a lower temperature of 300° C. or less using an RF magnetron sputtering method. The ZnO TFT may be fabricated on a plastic substrate susceptible to heat damage. Because all layers may be formed of transparent ZnO, a transparent ZnO TFT may be fabricated, which is useful in a bottom emitting type organic light emitting diode (OLED) display. Transparent ZnO is a ZnO-based material. As such, an interface characteristic of each stack may be high, making a higher quality ZnO TFT obtainable. Because the same material is used, additional processes (e.g., ion shower for providing a contact between a source and a drain) may not necessary. In addition, the presence of impurities created as a result of foreign elements may be decreased. The lower temperature process may contribute to increase durability of processing equipment and decrease fabrication costs.

The example embodiments described herein may be applied to various types of devices using a ZnO TFT (e.g., a display including a TFT that must be formed on a flexible plastic substrate or an OLED display).

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A zinc oxide (ZnO) thin film transistor (TFT), comprising:
a ZnO semiconductor channel;
a conductive ZnO gate forming an electric field around the ZnO semiconductor channel;
an ZnO gate insulator interposed between the conductive ZnO gate and the ZnO semiconductor channel; and
an insulating ZnO passivation layer on the ZnO semiconductor channel, the conductive ZnO gate and the ZnO gate insulator protecting the ZnO semiconductor channel, the conductive ZnO gate and the ZnO gate insulator.

2. The ZnO TFT of claim 1, wherein the ZnO semiconductor channel is formed of ZnO doped with a conductive material.

3. The ZnO TFT of claim 2, wherein the conductive ZnO gate is doped with a conductive material.

4. The ZnO TFT of claim 1, wherein the conductive ZnO gate is doped with a conductive material.

5. The ZnO TFT of claim 1, further comprising a source and a drain of ZnO doped with a conductive material.

6. The ZnO TFT of claim 5, wherein at least one of the conductive ZnO gate, the source and the drain includes amorphous ZnO.

7. The ZnO TFT of claim 6, wherein the ZnO semiconductor channel is formed of polycrystalline ZnO.

8. The ZnO TFT of claim 1, wherein the conductive ZnO gate and the ZnO gate insulator are formed on a substrate capable of heat deformation.

9. The ZnO TFT of claim 8, wherein the substrate is plastic.

10. A method of forming a thin film transistor (TFT), comprising:
forming a semiconductor channel;
forming a conductive gate having an electric field around the semiconductor channel;
forming an gate insulator between the conductive gate and the semiconductor channel; and
forming an insulating passivation layer on the semiconductor channel, the conductive gate and the gate insulator.

11. The method of claim 10, wherein the TFT, the semiconductor channel, the conductive gate, the gate insulator and the insulating passivation layer are formed of zinc oxide (ZnO).

12. The method of claim 11, further comprising forming a ZnO source and a ZnO drain; and doping the ZnO source and the ZnO drain with a conductive material.

13. The method of claim 12, wherein at least one of the conductive gate, the source and the drain includes amorphous ZnO.

14. The method of claim 13, wherein the ZnO semiconductor channel is formed of polycrystalline ZnO.

15. The method of claim 10, wherein forming the semiconductor channel includes doping the semiconductor channel with a conductive material.

16. The method of claim 15, wherein forming the conductive gate includes doping the conductive gate with a conductive material.

17. The method of claim 10, wherein forming the conductive gate includes doping the conductive gate with a conductive material.

18. The method of claim 10, further comprising forming a source and a drain; and doping the source and the drain with a conductive material.

19. The method of claim 10, wherein the TFT is formed at room temperature.

20. The method of claim 10, wherein the TFT is formed at a temperature of 300° C. or less.
